(19) United States
(12) Patent Application Publication
(10) Pub. No.: US 2025/0263582 A1
(43) Pub. Date: Aug. 21, 2025

(54) POLISHING LIQUID, POLISHING METHOD, COMPONENT MANUFACTURING METHOD, AND SEMICONDUCTOR COMPONENT MANUFACTURING METHOD

(71) Applicant: Resonac Corporation, Minato-ku, Tokyo (JP)

(72) Inventors: Taira ONUMA, Minato-ku, Tokyo (JP); Kohei HIRAO, Minato-ku, Tokyo (JP); Yasushi KURATA, Minato-ku, Tokyo (JP)

(21) Appl. No.: 18/856,974

(22) PCT Filed: Oct. 27, 2022
(86) PCT No.: PCT/JP2022/040219

§ 371 Date: Oct. 15, 2024

(51) Int. Cl. C09G 1/02; H01L 21/3105

(52) U.S. Cl. CPC C09G 1/02; H01L 21/31053

(57) ABSTRACT

A polishing liquid containing abrasive grains containing cerium oxide, at least one aromatic carboxylic acid compound selected from the group consisting of an aromatic carboxylic acid and a salt thereof, and a halide ion. A polishing method including polishing a member to be polished by using the above-described polishing liquid. A method for manufacturing a component, including obtaining a component by using a polished member polished by the above-described polishing method. A method for manufacturing a semiconductor component, including obtaining a semiconductor component by using a polished member polished by the above-described polishing method.

### TECHNICAL FIELD

The present disclosure relates to a polishing liquid, a polishing method, a method for manufacturing a component, a method for manufacturing a semiconductor component, and the like.

### BACKGROUND ART

In the manufacturing steps for electronic devices in recent years, the importance of processing technologies for density increase, micronization, and the like is increasing more and more. CMP (chemical mechanical polishing) technology, which is one of the processing technologies, has become an essential technology for formation of a shallow trench isolation (STI), flattening of a pre-metal insulating material or an interlayer insulating material, formation of a plug or an embedded metal wiring, or the like, in the manufacturing steps for electronic devices. As a polishing liquid used in CMP, a polishing liquid that contains abrasive grains containing cerium oxide is known (see, for example, Patent Literatures 1 and 2 below).

### CITATION LIST

### Patent Literature

Patent Literature 1: Japanese Unexamined Patent Publication No. H10-106994

Patent Literature 2: Japanese Unexamined Patent Publication No. H08-022970

### SUMMARY OF INVENTION

### Technical Problem

However, in the polishing liquid that contains abrasive grains containing cerium oxide, there is a case where it is difficult to achieve a high polishing rate of silicon oxide on a convex portion in polishing of a pattern wafer having a concavo-convex pattern consisting of a convex portion and a concave portion.

An object of an aspect of the present disclosure is to provide a polishing liquid capable of achieving a high polishing rate of silicon oxide on a convex portion in polishing of a pattern wafer having a concavo-convex pattern. An object of another aspect of the present disclosure is to provide a polishing method using the above-described polishing liquid. An object of another aspect of the present disclosure is to provide a method for manufacturing a component using the above-described polishing method. An object of another aspect of the present disclosure is to provide a method for manufacturing a semiconductor component using the above-described polishing method.

### Solution to Problem

The present disclosure relates to the following [1] to [19] and the like in several aspects.
[1]A polishing liquid containing abrasive grains containing cerium oxide, at least one aromatic carboxylic acid compound selected from the group consisting of an aromatic carboxylic acid and a salt thereof, and a halide ion.
[2] The polishing liquid described in [1], in which the halide ion includes at least one selected from the group consisting of fluoride ion, chloride ion, bromide ion, and iodide ion.
[3] The polishing liquid described in [1], in which the halide ion includes iodide ion.
[4] The polishing liquid described in any one of [1] to [3], in which a content of the halide ion is 0.01 to 5.0 mM.
[5] The polishing liquid described in any one of [1] to [4], in which the aromatic carboxylic acid compound includes at least one selected from the group consisting of benzoic acid and a salt thereof.
[6] The polishing liquid described in any one of [1] to [5], in which the aromatic carboxylic acid compound includes at least one selected from the group consisting of mandelic acid and a salt thereof.
[7] The polishing liquid described in any one of [1] to [6], in which a content of the aromatic carboxylic acid compound is 0.01 to 1% by mass.
[8] The polishing liquid described in any one of [1] to [7], further containing an alkali metal ion.
[9] The polishing liquid described in any one of [1] to [8], further containing a nitrogen-containing cation.
[10] The polishing liquid described in [9], in which the nitrogen-containing cation includes at least one selected from the group consisting of an ammonium ion and a quaternary ammonium cation.
[11] The polishing liquid described in any one of [1] to [10], in which a content of the abrasive grains is 0.1 to 5% by mass.
[12] The polishing liquid described in any one of [1] to [11], in which a zeta potential of the abrasive grains is positive.
[13] The polishing liquid described in any one of [1] to [12], further containing a cationic polymer.
[14] The polishing liquid described in [13], in which the cationic polymer includes a reaction product of a raw material containing at least dimethylamine and epichlorohydrin.
[15] The polishing liquid described in any one of [1] to [14], in which a pH is 2.00 to 5.00.
[16]A polishing method including polishing a member to be polished by using the polishing liquid described in any one of [1] to [15].
[17] The polishing method described in [16], in which the member to be polished contains silicon oxide.
[18]A method for manufacturing a component, including obtaining a component by using a polished member polished by the polishing method described in [16] or [17].
[19]A method for manufacturing a semiconductor component, including obtaining a semiconductor component by using a polished member polished by the polishing method described in [16] or [17].

### Advantageous Effects of Invention

According to an aspect of the present disclosure, it is possible to provide a polishing liquid capable of achieving a high polishing rate of silicon oxide on a convex portion in polishing of a pattern wafer having a concavo-convex pattern. According to another aspect of the present disclosure, it is possible to provide a polishing method using the above-described polishing liquid. According to another aspect of the present disclosure, it is possible to provide a method for manufacturing a component using the above-described polishing method. According to another aspect of the present disclosure, it is possible to provide a method for manufacturing a semiconductor component using the above-described polishing method.

### DESCRIPTION OF EMBODIMENTS

Hereinafter, embodiments of the present disclosure will be described. However, the present disclosure is not limited to the following embodiments.

In the present specification, a numerical range that has been indicated by use of “to” indicates the range that includes the numerical values which are described before and after “to”, as the minimum value and the maximum value, respectively. “A or more” in the numerical range means A and a range of more than A. “A or less” in the numerical range means A and a range of less than A. In the numerical ranges that are described stepwise in the present specification, the upper limit value or the lower limit value of the numerical range of a certain stage can be arbitrarily combined with the upper limit value or the lower limit value of the numerical range of another stage. In the numerical ranges that are described in the present specification, the upper limit value or the lower limit value of the numerical range may be replaced with the value shown in Examples. “A or B” may include either one of A and B, and may also include both of A and B. Materials listed as examples in the present specification can be used singly or in combinations of two or more, unless otherwise specified. When a plurality of substances corresponding to each component exist in the composition, the content of each component in the composition means the total amount of the plurality of substances that exist in the composition, unless otherwise specified. The term “film” includes a structure having a shape which is formed on a part, in addition to a structure having a shape which is formed on the whole surface, when the film has been observed as a plan view. The term “step” includes not only an independent step but also a step by which an intended action of the step is achieved, though the step cannot be clearly distinguished from other steps. The “alkyl group” may be linear, branched, or cyclic, unless otherwise specified. The term “abrasive grains” means a collective entity of a plurality of particles, and for convenience, one particle constituting the abrasive grains may be referred to as an abrasive grain.

### <Polishing Liquid>

A polishing liquid of the present embodiment contains abrasive grains containing cerium oxide, at least one aromatic carboxylic acid compound selected from the group consisting of an aromatic carboxylic acid and a salt thereof, and a halide ion. The polishing liquid of the present embodiment can be used as a CMP polishing liquid.

According to the polishing liquid of the present embodiment, it is possible to achieve a high polishing rate of silicon oxide (for example, silicon dioxide) on a convex portion in polishing of a pattern wafer having a concavo-convex pattern consisting of a convex portion and a concave portion, and for example, in an evaluation method described in Examples described below, it is possible to obtain a polishing rate of silicon oxide on a convex portion of, for example, 2500 nm/min or more (preferably, 3000 nm/min or more, 3500 nm/min or more, 4000 nm/min or more, 4500 nm/min or more, 5000 nm/min or more, or the like).

Although a factor responsible for obtaining a high polishing rate of silicon oxide on a convex portion in polishing of a pattern wafer is not necessarily clear, it is presumed to be as described below. However, the factor is not limited to the contents to be as follows.

That is, the halide ion is adsorbed to the surface of the abrasive grains containing cerium oxide, so that an active site for bonding between the cerium oxide of the abrasive grains and the silicon oxide of a member to be polished is easily formed. On the other hand, when the halide ion is adsorbed to the surface of the abrasive grains containing cerium oxide, the surface potential (zeta potential) of the abrasive grains decreases and the ionic strength in the polishing liquid increases, so that the electrostatic attraction (interaction) between the abrasive grains and the silicon oxide of the member to be polished is likely to be reduced.

In polishing of a convex portion in a pattern wafer, a pressure to be applied to the convex portion is higher than that to be applied to a concave portion, and a relatively high shear stress is applied, so that a large mechanical energy is easy to be imparted to the abrasive grains. In this case, the aforementioned active site of the abrasive grains containing cerium oxide reacts with the silicon oxide of the member to be polished to easily form a bond (for example, Ce—O—Si) between the cerium oxide and the silicon oxide, and it is easy to obtain a polishing-promoting effect having a greater impact than the aforementioned effect in which the electrostatic attraction is reduced. Thereby, it is possible to achieve a high polishing rate of silicon oxide on a convex portion in polishing of a pattern wafer.

In polishing of a pattern wafer having a concavo-convex pattern consisting of a convex portion and a concave portion, it is required to reduce the polishing rate of the concave portion in order to improve the flatness after polishing. Here, as the density of the convex portion in the pattern wafer is lower, the state of the concave portion is more likely to approach the state of a blanket wafer having no concavo-convex pattern. Therefore, from the viewpoint of reducing the polishing rate of a concave portion in a pattern wafer having a low density of a convex portion, it is required to reduce the polishing rate of the blanket wafer. In this regard, according to an embodiment of the polishing liquid of the present embodiment, in polishing of a blanket wafer having no concavo-convex pattern, the polishing rate of silicon oxide (for example, silicon dioxide) can be reduced, and for example, in an evaluation method described in Examples described below, it is possible to obtain a polishing rate of silicon oxide of, for example, 3000 Å/min or less (preferably, 2000 Å/min or less, 1000 Å/min or less, 800 Å/min or less, 600 Å/min or less, 500 Å/min or less, 300 Å/min or less, 100 Å/min or less, 60 Å/min or less, or the like). That is, according to an embodiment of the polishing liquid of the present embodiment, it is possible to achieve a high polishing rate of silicon oxide on a convex portion in polishing of a pattern wafer while reducing the polishing rate of silicon oxide in polishing of a blanket wafer.

Although a factor responsible for reducing the polishing rate of silicon oxide in polishing of a blanket wafer is not necessarily clear, it is presumed to be as described below. However, the factor is not limited to the contents to be as follows.

That is, as described above, when the halide ion is adsorbed to the surface of the abrasive grains containing cerium oxide, an active site for bonding between the cerium oxide of the abrasive grains and the silicon oxide of a member to be polished is easily formed, but the electrostatic attraction (interaction) between the abrasive grains and the silicon oxide of the member to be polished is likely to be reduced.

In polishing of a blanket wafer, a pressure to be applied to the blanket wafer is lower than that to be applied to a convex portion in a pattern wafer, and a large mechanical energy is difficult to be imparted to the abrasive grains. In this case, since a decrease in the electrostatic attraction between the abrasive grains and the silicon oxide of the member to be polished is likely to have a great impact, it is difficult to overcome the activation barrier for forming a bond (for example, Ce—O—Si) between the cerium oxide and the silicon oxide and difficult to obtain a polishing-promoting effect. Thereby, the polishing rate of silicon oxide in polishing of a blanket wafer is reduced.

The polishing liquid of the present embodiment contains abrasive grains containing cerium oxide. By using the abrasive grains containing cerium oxide, it is easy to obtain a high polishing rate of silicon oxide in a pattern wafer. The cerium oxide may be CeO₂ (cerium(IV) oxide, ceria), and may be Ce₂O₃ (cerium(III) oxide). The abrasive grains may contain a constituent material other than the cerium oxide. Examples of the constituent material for the abrasive grains other than the cerium oxide include inorganic materials such as silica (SiO₂), alumina, zirconia, titania, germania, and silicon carbide.

The content of the cerium oxide in the abrasive grains may be 90% by mass or more, 93% by mass or more, 95% by mass or more, more than 95% by mass, 98% by mass or more, 99% by mass or more, 99.5% by mass or more, or 99.9% by mass or more, on the basis of the whole abrasive grains (the whole abrasive grains contained in the polishing liquid, or the whole of one particle constituting the abrasive grains), from the viewpoint of easily obtaining a high polishing rate of silicon oxide in a pattern wafer. The abrasive grains may be an embodiment substantially composed of cerium oxide (an embodiment in which substantially 100% by mass of the abrasive grains are cerium oxide).

The zeta potential (surface potential) of the abrasive grains in the polishing liquid may be positive (the zeta potential may be more than 0 mV) from the viewpoint of easily obtaining a high polishing rate of silicon oxide in a pattern wafer. The zeta potential of the abrasive grains may be 1 mV or more, 5 mV or more, 10 mV or more, 15 mV or more, 20 mV or more, 21 mV or more, 22 mV or more, 23 mV or more, 24 mV or more, 24.5 mV or more, or 25 mV or more. The zeta potential of the abrasive grains may be 100 mV or less, 80 mV or less, 60 mV or less, 50 mV or less, 40 mV or less, 35 mV or less, 30 mV or less, 28 mV or less, 26 mV or less, 25 mV or less, 24.5 mV or less, 24 mV or less, 23 mV or less, 22 mV or less, 21 mV or less, or 20 mV or less. From these viewpoints, the zeta potential of the abrasive grains may be more than 0 mV and 100 mV or less, more than 0 mV and 50 mV or less, more than 0 mV and 30 mV or less, 10 to 100 mV, 10 to 50 mV, 10 to 30 mV, 20 to 100 mV, 20 to 50 mV, or 20 to 30 mV. The zeta potential of the abrasive grains can be measured by the method described in Examples described below.

The average particle diameter of the abrasive grains may be 10 nm or more, 30 nm or more, 50 nm or more, 80 nm or more, 100 nm or more, more than 100 nm, 120 nm or more, 150 nm or more, 180 nm or more, 200 nm or more, 220 nm or more, 250 nm or more, 270 nm or more, or 280 nm or more, from the viewpoint of easily obtaining a high polishing rate of silicon oxide in a pattern wafer. The average particle diameter of the abrasive grains may be 1000 nm or less, 800 nm or less, 600 nm or less, 500 nm or less, 450 nm or less, 400 nm or less, 380 nm or less, 350 nm or less, 330 nm or less, 300 nm or less, or 280 nm or less, from the viewpoint of easily suppressing generation of polishing scratches. From these viewpoints, the average particle diameter of the abrasive grains may be 10 to 1000 nm, 10 to 600 nm, 10 to 400 nm, 100 to 1000 nm, 100 to 600 nm, 100 to 400 nm, 200 to 1000 nm, 200 to 600 nm, or 200 to 400 nm. The average particle diameter of the abrasive grains can be measured by the method described in Examples described below.

The content of the abrasive grains may be in the following range on the basis of the total mass of the polishing liquid. The content of the abrasive grains may be 0.01% by mass or more, 0.05% by mass or more, 0.1% by mass or more, 0.3% by mass or more, 0.5% by mass or more, more than 0.5% by mass, 0.7% by mass or more, 0.8% by mass or more, 0.9% by mass or more, or 1% by mass or more, from the viewpoint of easily obtaining a high polishing rate of silicon oxide in a pattern wafer. The content of the abrasive grains may be 10% by mass or less, 8% by mass or less, 5% by mass or less, 4% by mass or less, 3% by mass or less, 2% by mass or less, 1.5% by mass or less, or 1% by mass or less, from the viewpoint of easily suppressing that an increase in polishing rate is saturated with respect to an increase in content of the abrasive grains, and the viewpoint of easily suppressing an increase in viscosity of the polishing liquid, the aggregation of the abrasive grains, an increase in polishing cost, generation of polishing scratches, or the like. From these viewpoints, the content of the abrasive grains may be 0.01 to 10% by mass, 0.1 to 10% by mass, 0.5 to 10% by mass, 0.01 to 5% by mass, 0.1 to 5% by mass, 0.5 to 5% by mass, 0.01 to 3% by mass, 0.1 to 3% by mass, or 0.5 to 3% by mass.

The polishing liquid of the present embodiment contains at least one aromatic carboxylic acid compound selected from the group consisting of an aromatic carboxylic acid (an aromatic compound having a carboxy group) and a salt thereof. Examples of the salt of the aromatic carboxylic acid include metal salts such as an alkali metal salt. Examples of the alkali metal salt include a sodium salt and a potassium salt.

The total of the carboxy group and the carboxylate group in the aromatic carboxylic acid compound, the number of carboxy groups in the aromatic carboxylic acid, or the number of carboxylate groups in the salt of the aromatic carboxylic acid may be 1 to 3 or 1 to 2 from the viewpoint of easily obtaining a high polishing rate of silicon oxide in a pattern wafer.

Examples of the aromatic ring of the aromatic carboxylic acid compound include a benzene ring, a naphthalene ring, an anthracene ring, a pyridine ring, and a quinoline ring. From the viewpoint of easily obtaining a high polishing rate of silicon oxide in a pattern wafer, the aromatic carboxylic acid compound may have a benzene ring. From the viewpoint of easily obtaining a high polishing rate of silicon oxide in a pattern wafer, the number of aromatic rings or the number of benzene rings in the aromatic carboxylic acid compound may be 1 to 3 or 1 to 2. The aromatic carboxylic acid compound may include a compound having a heteroaromatic ring, and may include a compound not having a heteroaromatic ring.

From the viewpoint of easily obtaining a high polishing rate of silicon oxide in a pattern wafer, the aromatic carboxylic acid compound may include at least one selected from the group consisting of an aromatic hydroxy acid (aromatic hydroxycarboxylic acid) and a salt thereof, and may include at least one selected from the group consisting of an aromatic α-hydroxy acid and a salt thereof.

Examples of the aromatic carboxylic acid include benzoic acid, a benzoic acid derivative, hydroxyphenylacetic acid, phthalic acid, a phthalic acid derivative, quinolinic acid, a quinoline derivative, and pyridinecarboxylic acid.

Examples of the benzoic acid derivative include compounds in which the hydrogen atom of the benzene ring of the benzoic acid is substituted with a substituent (such as an alkyl group, a hydroxy group, an amino group, or a sulfo group) different from the carboxy group, and examples thereof include hydroxybenzoic acid, aminobenzoic acid, and alkylsalicylic acid. Examples of the hydroxybenzoic acid include salicylic acid (2-hydroxybenzoic acid) and 4-hydroxybenzoic acid. Examples of the aminobenzoic acid include anthranilic acid. Examples of the alkylsalicylic acid include methylsalicylic acid (for example, 3-methylsalicylic acid). Examples of the hydroxyphenylacetic acid include mandelic acid (2-hydroxy-2-phenylacetic acid) and 4-hydroxyphenylacetic acid. Examples of the phthalic acid derivative include compounds in which the hydrogen atom of the benzene ring of the phthalic acid is substituted with a substituent (such as an alkyl group, a hydroxy group, an amino group, or a sulfo group) different from the carboxy group, and examples thereof include alkylphthalic acid, aminophthalic acid, and sulfophthalic acid. Examples of the alkylphthalic acid include methylphthalic acid (for example, 4-methylphthalic acid). Examples of the aminophthalic acid include 4-aminophthalic acid. Examples of the sulfophthalic acid include 4-sulfophthalic acid. Examples of the quinoline derivative include compounds in which the hydrogen atom of the pyridine ring of the quinolinic acid is substituted with a substituent (such as an alkyl group, a hydroxy group, an amino group, or a sulfo group) different from the carboxy group, and examples thereof include quinolinecarboxylic acid. Examples of the quinolinecarboxylic acid include quinaldic acid. Examples of the pyridinecarboxylic acid include picolinic acid and nicotinic acid.

From the viewpoint of easily obtaining a high polishing rate of silicon oxide in a pattern wafer, the aromatic carboxylic acid compound may include at least one selected from the group consisting of benzoic acid, a benzoic acid derivative, hydroxyphenylacetic acid, and salts thereof, may include at least one selected from the group consisting of benzoic acid, mandelic acid, anthranilic acid, and salts thereof, may include at least one selected from the group consisting of benzoic acid, mandelic acid, and salts thereof, may include at least one selected from the group consisting of benzoic acid and a salt thereof, and may include at least one selected from the group consisting of mandelic acid and a salt thereof.

The molecular weight of the aromatic carboxylic acid compound may be in the following range from the viewpoint of easily obtaining a high polishing rate of silicon oxide in a pattern wafer. The molecular weight of the aromatic carboxylic acid compound may be 80 or more, 90 or more, 100 or more, 110 or more, 120 or more, 125 or more, 130 or more, 140 or more, 145 or more, or 150 or more. The molecular weight of the aromatic carboxylic acid compound may be 1000 or less, less than 1000, 900 or less, 800 or less, 700 or less, 600 or less, 500 or less, 400 or less, 300 or less, 200 or less, 180 or less, 170 or less, 160 or less, 150 or less, 145 or less, 140 or less, 135 or less, 130 or less, or 125 or less. From these viewpoints, the molecular weight of the aromatic carboxylic acid compound may be 80 to 1000, 80 to 300, 80 to 180, 100 to 1000, 100 to 300, 100 to 180, 120 to 1000, 120 to 300, or 120 to 180.

The content of the benzoic acid may be in the following range on the basis of the total mass of the aromatic carboxylic acid compound (the total mass of the aromatic carboxylic acid compound contained in the polishing liquid of the present embodiment) from the viewpoint of easily obtaining a high polishing rate of silicon oxide in a pattern wafer. The content of the benzoic acid may be 30% by mass or more, 35% by mass or more, 40% by mass or more, 45% by mass or more, 50% by mass or more, more than 50% by mass, 55% by mass or more, 60% by mass or more, 65% by mass or more, or 70% by mass or more. The content of the benzoic acid may be 100% by mass or less, less than 100% by mass, 95% by mass or less, 90% by mass or less, 85% by mass or less, 80% by mass or less, or 75% by mass or less. From these viewpoints, the content of the benzoic acid may be 30 to 100% by mass, 30 to 90% by mass, 30 to 80% by mass, 50 to 100% by mass, 50 to 90% by mass, 50 to 80% by mass, 60 to 100% by mass, 60 to 90% by mass, or 60 to 80% by mass.

As the content of the hydroxyphenylacetic acid or the content of the mandelic acid, a content A1 may be in the following range on the basis of the total mass of the aromatic carboxylic acid compound (the total mass of the aromatic carboxylic acid compound contained in the polishing liquid of the present embodiment) from the viewpoint of easily obtaining a high polishing rate of silicon oxide in a pattern wafer. The content A1 may be more than 0% by mass, 5% by mass or more, 10% by mass or more, 15% by mass or more, 20% by mass or more, or 25% by mass or more. The content A1 may be 70% by mass or less, 65% by mass or less, 60% by mass or less, 55% by mass or less, 50% by mass or less, less than 50% by mass, 45% by mass or less, 40% by mass or less, 35% by mass or less, or 30% by mass or less. From these viewpoints, the content A1 may be more than 0% by mass and 70% by mass or less, more than 0% by mass and 50% by mass or less, more than 0% by mass and 40% by mass or less, 10 to 70% by mass, 10 to 50% by mass, 10 to 40% by mass, 20 to 70% by mass, 20 to 50% by mass, or 20 to 40% by mass.

As the content of the hydroxyphenylacetic acid or the content of mandelic acid, a content A2 may be in the following range on the basis of the total mass of benzoic acid from the viewpoint of easily obtaining a high polishing rate of silicon oxide in a pattern wafer. The content A2 may be 5% by mass or more, 10% by mass or more, 15% by mass or more, 20% by mass or more, 25% by mass or more, 30% by mass or more, or 35% by mass or more. The content A2 may be 80% by mass or less, 75% by mass or less, 70% by mass or less, 65% by mass or less, 60% by mass or less, 55% by mass or less, 50% by mass or less, less than 50% by mass, 45% by mass or less, or 40% by mass or less. From these viewpoints, the content A2 may be 5 to 80% by mass, 5 to 60% by mass, 5 to 40% by mass, 20 to 80% by mass, 20 to 60% by mass, 20 to 40% by mass, 30 to 80% by mass, 30 to 60% by mass, or 30 to 40% by mass.

The content of the aromatic carboxylic acid compound may be in the following range on the basis of the total mass of the polishing liquid from the viewpoint of easily obtaining a high polishing rate of silicon oxide in a pattern wafer. The content of the aromatic carboxylic acid compound may be 0.001% by mass or more, 0.005% by mass or more, 0.010% by mass or more, 0.03% by mass or more, 0.05% by mass or more, 0.06% by mass or more, 0.08% by mass or more, 0.10% by mass or more, more than 0.1% by mass, 0.12% by mass or more, 0.15% by mass or more, 0.16% by mass or more, 0.18% by mass or more, or 0.2% by mass or more. The content of the aromatic carboxylic acid compound may be 10% by mass or less, 8% by mass or less, 5% by mass or less, 3% by mass or less, 2% by mass or less, 1% by mass or less, 0.8% by mass or less, 0.6% by mass or less, 0.5% by mass or less, 0.4% by mass or less, or 0.3% by mass or less. From these viewpoints, the content of the aromatic carboxylic acid compound may be 0.001 to 10% by mass, 0.001 to 1% by mass, 0.001 to 0.5% by mass, 0.01 to 10% by mass, 0.01 to 1% by mass, 0.01 to 0.5% by mass, 0.1 to 10% by mass, 0.1 to 1% by mass, or 0.1 to 0.5% by mass.

The content of the benzoic acid may be in the following range on the basis of the total mass of the polishing liquid from the viewpoint of easily obtaining a high polishing rate of silicon oxide in a pattern wafer. The content of the benzoic acid may be 0.0010% by mass or more, 0.005% by mass or more, 0.01% by mass or more, 0.03% by mass or more, 0.05% by mass or more, 0.06% by mass or more, 0.08% by mass or more, 0.1% by mass or more, more than 0.1% by mass, 0.12% by mass or more, 0.15% by mass or more, or 0.16% by mass or more. The content of the benzoic acid may be 10% by mass or less, 8% by mass or less, 5% by mass or less, 30% by mass or less, 2% by mass or less, 1% by mass or less, 0.8% by mass or less, 0.6% by mass or less, 0.5% by mass or less, 0.4% by mass or less, 0.3% by mass or less, 0.2% by mass or less, 0.18% by mass or less, or 0.16% by mass or less. From these viewpoints, the content of the benzoic acid may be 0.001 to 10% by mass, 0.001 to 1% by mass, 0.001 to 0.5% by mass, 0.01 to 10% by mass, 0.01 to 1% by mass, 0.01 to 0.5% by mass, 0.1 to 10% by mass, 0.1 to 1% by mass, or 0.1 to 0.5% by mass.

As the content of the hydroxyphenylacetic acid or the content of the mandelic acid, a content A3 may be in the following range on the basis of the total mass of the polishing liquid from the viewpoint of easily obtaining a high polishing rate of silicon oxide in a pattern wafer. The content A3 may be 0.001% by mass or more, 0.005% by mass or more, 0.01% by mass or more, 0.03% by mass or more, 0.05% by mass or more, or 0.06% by mass or more. The content A3 may be 10% by mass or less, 8% by mass or less, 5% by mass or less, 3% by mass or less, 2% by mass or less, 1% by mass or less, 0.8% by mass or less, 0.6% by mass or less, 0.5% by mass or less, 0.4% by mass or less, 0.3% by mass or less, 0.2% by mass or less, 0.18% by mass or less, 0.16% by mass or less, 0.15% by mass or less, 0.12% by mass or less, 0.1% by mass or less, 0.08% by mass or less, or 0.06% by mass or less. From these viewpoints, the content A3 may be 0.001 to 10% by mass, 0.001 to 1% by mass, 0.001 to 0.5% by mass, 0.01 to 10% by mass, 0.01 to 1% by mass, 0.01 to 0.5% by mass, 0.05 to 10% by mass, 0.05 to 1% by mass, or 0.05 to 0.5% by mass.

A mass ratio A4 (the aromatic carboxylic acid compound/the abrasive grains) of the content of the aromatic carboxylic acid compound with respect to the content of the abrasive grains may be in the following range from the viewpoint of easily obtaining a high polishing rate of silicon oxide in a pattern wafer. The mass ratio A4 may be 0.001 or more, 0.005 or more, 0.01 or more, 0.03 or more, 0.05 or more, 0.06 or more, 0.08 or more, 0.1 or more, 0.12 or more, 0.15 or more, 0.16 or more, 0.18 or more, or 0.2 or more. The mass ratio A4 may be 10 or less, 8 or less, 5 or less, 3 or less, 2 or less, 1 or less, less than 1, 0.8 or less, 0.6 or less, 0.5 or less, 0.4 or less, or 0.3 or less. From these viewpoints, the mass ratio A4 may be 0.001 to 10, 0.001 to 1, 0.001 to 0.5, 0.01 to 10, 0.01 to 1, 0.01 to 0.5, 0.1 to 10, 0.1 to 1, or 0.1 to 0.5.

A mass ratio A5 (the benzoic acid/the abrasive grains) of the content of the benzoic acid with respect to the content of the abrasive grains may be in the following range from the viewpoint of easily obtaining a high polishing rate of silicon oxide in a pattern wafer. The mass ratio A5 may be 0.001 or more, 0.005 or more, 0.01 or more, 0.03 or more, 0.05 or more, 0.06 or more, 0.08 or more, 0.1 or more, 0.12 or more, 0.15 or more, or 0.16 or more. The mass ratio A5 may be 10 or less, 8 or less, 5 or less, 3 or less, 2 or less, 1 or less, less than 1, 0.8 or less, 0.6 or less, 0.5 or less, 0.4 or less, 0.3 or less, 0.2 or less, 0.18 or less, or 0.16 or less. From these viewpoints, the mass ratio A5 may be 0.001 to 10, 0.001 to 1, 0.001 to 0.5, 0.01 to 10, 0.01 to 1, 0.01 to 0.5, 0.1 to 10, 0.1 to 1, or 0.1 to 0.5.

As the mass ratio (the hydroxyphenylacetic acid/the abrasive grains) of the hydroxyphenylacetic acid with respect to the content of the abrasive grains or the mass ratio (the mandelic acid/the abrasive grains) of the content of the mandelic acid with respect to the content of the abrasive grains, a mass ratio A6 may be in the following range from the viewpoint of easily obtaining a high polishing rate of silicon oxide in a pattern wafer. The mass ratio A6 may be 0.001 or more, 0.005 or more, 0.01 or more, 0.03 or more, 0.05 or more, or 0.06 or more. The mass ratio A6 may be 10 or less, 8 or less, 5 or less, 3 or less, 2 or less, 1 or less, less than 1, 0.8 or less, 0.6 or less, 0.5 or less, 0.4 or less, 0.3 or less, 0.2 or less, 0.18 or less, 0.16 or less, 0.15 or less, 0.12 or less, 0.1 or less, 0.08 or less, or 0.06 or less. From these viewpoints, the mass ratio A6 may be 0.001 to 10, 0.001 to 1, 0.001 to 0.5, 0.01 to 10, 0.01 to 1, 0.01 to 0.5, 0.05 to 10, 0.05 to 1, or 0.05 to 0.5.

The polishing liquid of the present embodiment contains a halide ion. In the polishing liquid of the present embodiment, the halide ion may be bonded to a counter cation, and may be free without being bonded to a counter cation. As the counter cation, a cation described below can be used.

Examples of the halide ion include fluoride ion, chloride ion, bromide ion, and iodide ion. From the viewpoint of easily obtaining a high polishing rate of silicon oxide in a pattern wafer and the viewpoint of easily reducing the polishing rate of silicon oxide in a blanket wafer, the halide ion may include at least one selected from the group consisting of fluoride ion, chloride ion, bromide ion, and iodide ion. From the viewpoint of easily obtaining a high polishing rate of silicon oxide in a pattern wafer, the halide ion may include at least one selected from the group consisting of fluoride ion, chloride ion, and iodide ion, may include at least one selected from the group consisting of fluoride ion and iodide ion, and may include iodide ion. From the viewpoint of easily reducing the polishing rate of silicon oxide in a blanket wafer, the halide ion may include at least one selected from the group consisting of chloride ion, bromide ion, and iodide ion, may include at least one selected from the group consisting of bromide ion and iodide ion, and may include iodide ion.

The content of the halide ion may be in the following range on the basis of the total amount of the polishing liquid from the viewpoint of easily obtaining a high polishing rate of silicon oxide in a pattern wafer and the viewpoint of easily reducing the polishing rate of silicon oxide in a blanket wafer. The content of the halide ion may be 0.01 mM or more, 0.05 mM or more, 0.10 mM or more, 0.20 mM or more, 0.30 mM or more, 0.40 mM or more, 0.45 mM or more, 0.50 mM or more, 0.55 mM or more, 0.60 mM or more, 0.65 mM or more, or 0.69 mM or more. The content of the halide ion may be 5.0 mM or less, 3.0 mM or less, 1.0 mM or less, 0.90 mM or less, 0.80 mM or less, 0.75 mM or less, 0.70 mM or less, 0.69 mM or less, 0.65 mM or less, or 0.60 mM or less. From these viewpoints, the content of the halide ion may be 0.01 to 5.0 mM, 0.01 to 3.0 mM, 0.01 to 1.0 mM, 0.10 to 5.0 mM, 0.10 to 3.0 mM, 0.10 to 1.0 mM, 0.30 to 5.0 mM, 0.30 to 3.0 mM, or 0.30 to 1.0 mM.

The polishing liquid of the present embodiment may contain a salt containing a halide ion. The salt containing a halide ion is a salt containing a halide ion and a counter cation, and as the counter cation, a cation described below can be used.

The content of the salt containing a halide ion may be in the following range on the basis of the total mass of the polishing liquid from the viewpoint of easily obtaining a high polishing rate of silicon oxide in a pattern wafer and the viewpoint of easily reducing the polishing rate of silicon oxide in a blanket wafer. The content of the salt containing a halide ion may be 0.001% by mass or more, 0.002% by mass or more, 0.003% by mass or more, 0.004% by mass or more, 0.005% by mass or more, 0.006% by mass or more, 0.007% by mass or more, 0.008% by mass or more, 0.009% by mass or more, 0.01% by mass or more, 0.012% by mass or more, 0.015% by mass or more, 0.02% by mass or more, or 0.025% by mass or more. The content of the salt containing a halide ion may be 1% by mass or less, 0.5% by mass or less, 0.1% by mass or less, 0.05% by mass or less, 0.03% by mass or less, 0.025% by mass or less, 0.02% by mass or less, 0.015% by mass or less, 0.012% by mass or less, 0.01% by mass or less, 0.009% by mass or less, 0.008% by mass or less, 0.007% by mass or less, 0.006% by mass or less, 0.005% by mass or less, 0.004% by mass or less, or 0.003% by mass or less. From these viewpoints, the content of the salt containing a halide ion may be 0.001 to 1% by mass, 0.001 to 0.1% by mass, 0.001 to 0.03% by mass, 0.005 to 1% by mass, 0.005 to 0.1% by mass, 0.005 to 0.03% by mass, 0.008 to 1% by mass, 0.008 to 0.1% by mass, or 0.008 to 0.03% by mass.

A mass ratio B1 (the salt containing a halide ion/the abrasive grains) of the content of the salt containing a halide ion with respect to the content of the abrasive grains may be in the following range from the viewpoint of easily obtaining a high polishing rate of silicon oxide in a pattern wafer and the viewpoint of easily reducing the polishing rate of silicon oxide in a blanket wafer. The mass ratio B1 may be 0.001 or more, 0.002 or more, 0.003 or more, 0.004 or more, 0.005 or more, 0.006 or more, 0.007 or more, 0.008 or more, 0.009 or more, 0.01 or more, 0.012 or more, 0.015 or more, 0.02 or more, or 0.025 or more. The mass ratio B1 may be 1 or less, less than 1, 0.5 or less, 0.1 or less, 0.05 or less, 0.03 or less, 0.025 or less, 0.02 or less, 0.015 or less, 0.012 or less, 0.01 or less, 0.009 or less, 0.008 or less, 0.007 or less, 0.006 or less, 0.005 or less, 0.004 or less, or 0.003 or less. From these viewpoints, the mass ratio B1 may be 0.001 to 1, 0.001 to 0.1, 0.001 to 0.03, 0.005 to 1, 0.005 to 0.1, 0.005 to 0.03, 0.008 to 1, 0.008 to 0.1, or 0.008 to 0.03.

A mass ratio B2 (the salt containing a halide ion/the aromatic carboxylic acid compound) of the content of the salt containing a halide ion with respect to the content of the aromatic carboxylic acid compound may be in the following range from the viewpoint of easily obtaining a high polishing rate of silicon oxide in a pattern wafer and the viewpoint of easily reducing the polishing rate of silicon oxide in a blanket wafer. The mass ratio B2 may be 0.001 or more, 0.005 or more, 0.01 or more, 0.015 or more, 0.02 or more, 0.03 or more, 0.04 or more, 0.05 or more, 0.08 or more, or 0.1 or more. The mass ratio B2 may be 1 or less, less than 1, 0.5 or less, 0.2 or less, 0.1 or less, 0.08 or less, 0.05 or less, 0.04 or less, 0.03 or less, 0.02 or less, or 0.015 or less. From these viewpoints, the mass ratio B2 may be 0.001 to 1, 0.001 to 0.5, 0.001 to 0.2, 0.005 to 1, 0.005 to 0.5, 0.005 to 0.2, 0.015 to 1, 0.015 to 0.5, or 0.015 to 0.2.

The polishing liquid of the present embodiment may contain a cation. In the polishing liquid of the present embodiment, the cation may be bonded to a counter anion, and may be free without being bonded to a counter anion.

Examples of the cation include a metal ion (for example, an alkali metal ion) and a nitrogen-containing cation. The polishing liquid of the present embodiment may be an embodiment containing a metal ion, may be an embodiment containing an alkali metal ion, and may be an embodiment containing a nitrogen-containing cation. The cation may be a counter cation in the aforementioned salt of the aromatic carboxylic acid, and may be a counter cation with respect to the aforementioned halide ion.

Examples of the alkali metal ion include sodium ion and potassium ion. From the viewpoint of easily obtaining a high polishing rate of silicon oxide in a pattern wafer, the alkali metal ion may include at least one selected from the group consisting of sodium ion and potassium ion, and may include potassium ion.

Examples of the nitrogen-containing cation include an ammonium ion (NH₄⁺), a primary ammonium cation, a secondary ammonium cation, a tertiary ammonium cation, a quaternary ammonium cation, an imidazolium cation, a pyridinium cation, a pyrrolidinium cation, and a guanidinium cation. From the viewpoint of easily obtaining a high polishing rate of silicon oxide in a pattern wafer, the nitrogen-containing cation may include at least one selected from the group consisting of an ammonium ion, a primary ammonium cation, a secondary ammonium cation, a tertiary ammonium cation, and a quaternary ammonium cation, and may include at least one selected from the group consisting of an ammonium ion and a quaternary ammonium cation.

From the viewpoint of easily obtaining a high polishing rate of silicon oxide in a pattern wafer, in the quaternary ammonium cation, the number of alkyl groups bonded to the nitrogen atom or the number of unsubstituted alkyl groups bonded to the nitrogen atom may be 1 to 4, 2 to 4, or 3 to 4.

From the viewpoint of easily obtaining a high polishing rate of silicon oxide in a pattern wafer, the quaternary ammonium cation may have an alkyl group having the following carbon numbers as the alkyl group bonded to the nitrogen atom or the unsubstituted alkyl group bonded to the nitrogen atom. The number of carbon atoms of the alkyl group may be 1 or more, 2 or more, 3 or more, or 4 or more. The number of carbon atoms of the alkyl group may be 12 or less, 10 or less, 8 or less, 6 or less, or 4 or less. From these viewpoints, the number of carbon atoms of the alkyl group may be 1 to 12, 1 to 8, 1 to 4, 2 to 12, 2 to 8, 2 to 4, 3 to 12, 3 to 8, or 3 to 4.

From the viewpoint of easily obtaining a high polishing rate of silicon oxide in a pattern wafer, the quaternary ammonium cation may include a tetraalkylammonium cation, and may include at least one selected from the group consisting of a tetramethylammonium cation, a tetraethylammonium cation, a tetrapropylammonium cation, and a tetrabutylammonium cation.

From the viewpoint of easily obtaining a high polishing rate of silicon oxide in a pattern wafer and the viewpoint of easily reducing the polishing rate of silicon oxide in a blanket wafer, the polishing liquid of the present embodiment may contain at least one selected from the group consisting of potassium iodide, ammonium iodide, tetraalkylammonium iodide (for example, tetrabutylammonium iodide), ammonium bromide, ammonium chloride, and ammonium fluoride, as the salt containing a halide ion and a counter cation.

From the viewpoint of easily obtaining a high polishing rate of silicon oxide in a pattern wafer and the viewpoint of easily reducing the polishing rate of silicon oxide in a blanket wafer, the polishing liquid of the present embodiment may contain a nonionic polymer (excluding a compound corresponding to the aromatic carboxylic acid compound). Examples of the nonionic polymer include ether-based surfactants such as polyglycerol, polyglycerol fatty acid ester, polyoxyethylene distyrenated phenyl ether, polyoxyethylene sorbitan monolaurate, polyoxyethylene lauryl ether, polyoxypropylene polyoxyethylene alkyl ether, polyoxyethylene alkyl allyl ether, polyoxyethylene polyoxypropylene ether derivatives, polyoxypropylene glyceryl ether, polyethylene glycol, methoxypolyethylene glycol, and oxyethylene adducts of acethylene-based diols; ester-type surfactants such as sorbitan fatty acid ester and glycerol borate fatty acid ester; amino ether-type surfactants such as polyoxyethylene alkylamine; ether ester-type surfactants such as polyoxyethylene glycerol borate fatty acid ester and polyoxyethylene alkyl ester; alkanolamide-type surfactants such as fatty acid alkanolamide and polyoxyethylene fatty acid alkanolamide; polyvinylpyrrolidone; nonionic polyacrylamide; and nonionic polydimethylacrylamide. From the viewpoint of easily obtaining a high polishing rate of silicon oxide in a pattern wafer and the viewpoint of easily reducing the polishing rate of silicon oxide in a blanket wafer, the nonionic polymer may include an ether type surfactant, and may include polyglycerol.

The molecular weight of the nonionic polymer or the molecular weight of the polyglycerol may be in the following range from the viewpoint of easily obtaining a high polishing rate of silicon oxide in a pattern wafer and the viewpoint of easily reducing the polishing rate of silicon oxide in a blanket wafer. The molecular weight may be 100 or more, 200 or more, 300 or more, 350 or more, 400 or more, 450 or more, 500 or more, 550 or more, 600 or more, 650 or more, 700 or more, or 750 or more. The molecular weight may be 5000 or less, 4000 or less, 3000 or less, 2000 or less, 1500 or less, 1200 or less, 1000 or less, 900 or less, 800 or less, or 750 or less. From these viewpoints, the molecular weight may be 100 to 5000, 100 to 3000, 100 to 1000, 300 to 5000, 300 to 3000, 300 to 1000, 500 to 5000, 500 to 3000, or 500 to 1000. The molecular weight may be, for example, a weight average molecular weight. The weight average molecular weight can be obtained, for example, by measuring gel permeation chromatography (GPC) under the following conditions and converting in terms of polyethylene glycol/polyethylene oxide.
Equipment used (detector): “RID-10A” differential refractometer for liquid chromatograph manufactured by SHIMADZU CORPORATION
Pump: “RID-10A” manufactured by SHIMADZU CORPORATION
Degassing apparatus: “DGU-20A3R” manufactured by SHIMADZU CORPORATION
Data processing: “LC solution” manufactured by SHIMADZU CORPORATION
Column: “Gelpak GL-W530+Gelpak GL-W540” manufactured by Showa Denko Materials Techno Service Co., LTD., inner diameter 10.7 mm×300 mm
Eluent: 50 mM-Na₂HAPO₄ aqueous solution/acetonitrile=90/10 (v/v)
Measurement temperature: 40° C.
Flow rate: 1.0 mL/min
Measurement time: 60 minutes
Sample: Sample prepared by adjusting a concentration with a solution having the same composition as the eluent so that the resin component concentration becomes 0.2% by mass and filtering through a 0.45 μm membrane filter
Injection amount: 100 μL
Standard substance: Polyethylene glycol/polyethylene oxide manufactured by Tosoh Corporation

The content of the nonionic polymer may be in the following range on the basis of the total mass of the polishing liquid from the viewpoint of easily obtaining a high polishing rate of silicon oxide in a pattern wafer and the viewpoint of easily reducing the polishing rate of silicon oxide in a blanket wafer. The content of the nonionic polymer may be 0.010% by mass or more, 0.05% by mass or more, 0.1% by mass or more, 0.15% by mass or more, and 0.2% by mass or more. The content of the nonionic polymer may be 5% by mass or less, 3% by mass or less, 1% by mass or less, 0.5% by mass or less, 0.3% by mass or less, or 0.2% by mass or less. From these viewpoints, the content of the nonionic polymer may be 0.01 to 5% by mass, 0.01 to 1% by mass, 0.01 to 0.5% by mass, 0.05 to 5% by mass, 0.05 to 1% by mass, 0.05 to 0.5% by mass, 0.1 to 5% by mass, 0.1 to 1% by mass, or 0.1 to 0.5% by mass.

From the viewpoint of easily reducing the polishing rate of silicon oxide in a blanket wafer, the polishing liquid of the present embodiment may contain a cationic polymer (excluding a compound corresponding to the aromatic carboxylic acid compound). The cationic polymer has a cationic monomer as a monomer unit. Examples of the cationic monomer include ethyleneimine, allylamine, dimethyl (meth)acrylamide, diallylamine, methyldiallylamine, (meth)acrylic acid, diallyldimethylammonium chloride, (meth)acrylamide, dimethylamine, epichlorohydrin, ammonia, dimethylaminoethyl (meth)acrylate, dicyandiamide, diethylenetriamine, 3-(meth)acrylamidopropyl trimethylammonium methylchloride, 3-(meth)acrylamidopropyl trimethylammonium methylsulfate, 2-((meth)acryloyloxy)ethyltrimethylammonium methylsulfate, 2-((meth)acryloyloxy)ethyltrimethylammonium chloride, vinylpyrrolidone-dimethylaminoethyl (meth)acrylate diethyl sulfate, diallyldimethylammonium chloride-(meth)acrylamide, and diallylmethylethylammonium ethyl sulfate.

From the viewpoint of easily reducing the polishing rate of silicon oxide in a blanket wafer, the cationic polymer may include a reaction product (for example, a condensate) of a raw material containing at least dimethylamine and epichlorohydrin, and may include a reaction product (for example, a condensate) of a raw material containing at least dimethylamine, ammonia, and epichlorohydrin. The raw material providing a reaction product may contain a compound other than dimethylamine, ammonia, and epichlorohydrin. From the viewpoint of easily reducing the polishing rate of silicon oxide in a blanket wafer, the cationic polymer may include a compound having a structure represented by the following formula. From the viewpoint of easily reducing the polishing rate of silicon oxide in a blanket wafer, the cationic polymer may include at least one selected from the group consisting of dimethylamine/epichlorohydrin condensate (polycondensate) and dimethylamine/ammonia/epichlorohydrin condensate (polycondensate).

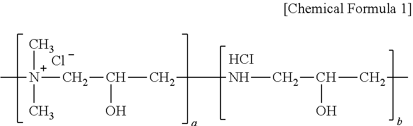

[In the formula, “a” represents an integer of 1 or more, and “b” represents an integer of 0 or more (for example, 1 or more).]

The content of the cationic polymer may be in the following range on the basis of the total mass of the polishing liquid from the viewpoint of easily reducing the polishing rate of silicon oxide in a blanket wafer. The content of the cationic polymer may be 0.0001% by mass or more, 0.0003% by mass or more, 0.0005% by mass or more, 0.0008% by mass or more, 0.0010% by mass or more, 0.0012% by mass or more, or 0.0015% by mass or more. The content of the cationic polymer may be 0.1% by mass or less, 0.05% by mass or less, 0.01% by mass or less, 0.005% by mass or less, 0.003% by mass or less, or 0.002% by mass or less. From these viewpoints, the content of the cationic polymer may be 0.0001 to 0.1% by mass, 0.0001 to 0.01% by mass, 0.0001 to 0.005% by mass, 0.0005 to 0.1% by mass, 0.0005 to 0.01% by mass, 0.0005 to 0.005% by mass, 0.001 to 0.1% by mass, 0.001 to 0.01% by mass, or 0.001 to 0.005% by mass.

The polishing liquid of the present embodiment may contain water. Water may be contained as a residue excluding other constituent components from the polishing liquid.

The polishing liquid of the present embodiment may contain a component other than the aforementioned components. Examples of such a component include an acid component, an organic solvent, an anticorrosive agent, a basic hydroxide, and a peroxide. The polishing liquid of the present embodiment may not contain at least one of these components. The polishing liquid of the present embodiment may not contain at least one selected from the group consisting of starch and cyclodextrin.

The pH of the polishing liquid of the present embodiment may be in the following range from the viewpoint of easily obtaining a high polishing rate of silicon oxide in a pattern wafer and the viewpoint of easily reducing the polishing rate of silicon oxide in a blanket wafer. The pH of the polishing liquid may be 1.00 or more, more than 1.00, 1.50 or more, more than 1.50, 2.00 or more, more than 2.00, 2.20 or more, 2.50 or more, more than 2.50, 2.60 or more, 2.80 or more, 3.00 or more, or more than 3.00. The pH of the polishing liquid may be 7.00 or less, less than 7.00, 6.50 or less, 6.00 or less, less than 6.00, 5.50 or less, 5.00 or less, less than 5.00, 4.50 or less, 4.00 or less, less than 4.00, 3.80 or less, 3.50 or less, 3.30 or less, 3.20 or less, 3.10 or less, 3.00 or less, or less than 3.00. From these viewpoints, the pH of the polishing liquid may be 1.00 to 7.00, 1.00 to 5.00, 1.00 to 3.50, 2.00 to 7.00, 2.00 to 5.00, 2.00 to 3.50, 2.50 to 7.00, 2.50 to 5.00, or 2.50 to 3.50. The pH of the polishing liquid can be measured by the method described in Examples described below.

The polishing liquid of the present embodiment may be stored as a stock solution for a polishing liquid in such a state that the amount of water is more reduced than that during use. The stock solution for a polishing liquid is a stock solution for obtaining the polishing liquid, and the stock solution for a polishing liquid is diluted with water before use or during use to obtain the polishing liquid. The dilution ratio is, for example, 1.5 times or more.

The polishing liquid of the present embodiment may be stored as a one-pack polishing liquid containing at least abrasive grains, an aromatic carboxylic acid compound, and a halide ion, and may be stored as a multi-pack polishing liquid having a slurry (first liquid) and an additive liquid (second liquid). In the multi-pack polishing liquid, the constituent components of the polishing liquid are divided into the slurry and the additive liquid so that the slurry and the additive liquid are mixed to form the polishing liquid. For example, the multi-pack polishing liquid may be an embodiment in which the slurry contains at least abrasive grains and water, the additive liquid contains at least an aromatic carboxylic acid compound and water, and the halide ion is contained in at least one selected from the group consisting of the slurry and the additive liquid. The constituent components of the polishing liquid may be stored separately in three or more liquids. In the multi-pack polishing liquid, the polishing liquid may be prepared by mixing the slurry and the additive liquid immediately before polishing or during polishing. The polishing liquid may be prepared by supplying each of the slurry and the additive liquid of the multi-pack polishing liquid onto a polishing platen and mixing the slurry and the additive liquid on the polishing platen.

### <Polishing Method>

A polishing method of the present embodiment includes a polishing step of polishing a member to be polished by using the polishing liquid of the present embodiment. In the polishing step, the surface to be polished of the member to be polished can be polished. In the polishing step, at least a part of the member to be polished can be removed by polishing. The member to be polished may contain silicon oxide (for example, silicon dioxide). The polishing liquid used in the polishing step may be the aforementioned one-pack polishing liquid, may be a polishing liquid obtained by diluting the aforementioned stock solution for a polishing liquid with water, and may be a polishing liquid obtained by mixing the slurry and the additive liquid of the aforementioned multi-pack polishing liquid. The member to be polished is not particularly limited, but may be a wafer (for example, a semiconductor wafer), and may be a chip (for example, a semiconductor chip). The member to be polished may be a wiring board and may be a circuit board.

### <Manufacturing Method and the Like>

A method for producing a component of the present embodiment includes a component producing step of obtaining a component by using a polished member (base substrate) polished by the polishing method of the present embodiment. A component of the present embodiment is a component obtained by the method of producing a component of the present embodiment. The component of the present embodiment is not particularly limited, and may be an electronic component (for example, a semiconductor component such as a semiconductor package), may be a wafer (for example, a semiconductor wafer), and may be a chip (for example, a semiconductor chip). As an embodiment of the method for producing a component of the present embodiment, in a method for producing an electronic component of the present embodiment, an electronic component is obtained by using a polished member polished by the polishing method of the present embodiment. As an embodiment of the method for producing a component of the present embodiment, in a method for producing a semiconductor component of the present embodiment, a semiconductor component (for example, a semiconductor package) is obtained by using a polished member polished by the polishing method of the present embodiment. The method for producing a component of the present embodiment may include a polishing step of polishing a member to be polished by the polishing method of the present embodiment before the component producing step.

The method for producing a component of the present embodiment may include, as an embodiment of the component producing step, an individually dividing step of dividing a polished member (base substrate) polished by the polishing method of the present embodiment into individual pieces. The individually dividing step may be, for example, a step of dicing a wafer (for example, a semiconductor wafer) polished by the polishing method of the present embodiment to obtain chips (for example, semiconductor chips). As an embodiment of the method for producing a component of the present embodiment, the method for producing an electronic component of the present embodiment may include a step of obtaining an electronic component (for example, a semiconductor component) by individually dividing a polished member polished by the polishing method of the present embodiment into individual pieces. As an embodiment of the method for producing a component of the present embodiment, the method for producing a semiconductor component of the present embodiment may include a step of obtaining a semiconductor component (for example, a semiconductor package) by individually dividing a polished member polished by the polishing method of the present embodiment into individual pieces.

The method for producing a component of the present embodiment may include, as an embodiment of the component producing step, a connecting step of connecting (for example, electrically connecting) a polished member (base substrate) polished by the polishing method of the present embodiment to another body to be connected. The body to be connected that is connected to the polished member polished by the polishing method of the present embodiment is not particularly limited, and may be a polished member polished by the polishing method of the present embodiment, and may be a body to be connected different from the polished member polished by the polishing method of the present embodiment. In the connecting step, the polished member and the body to be connected may be directly connected to each other (connected in a state where the polished member and the body to be connected are in contact with each other), and the polished member and the body to be connected may be connected via another member (such as a conductive member). The connecting step can be performed before the individually dividing step, after the individually dividing step, or before and after the individually dividing step.

The connecting step may be a step of connecting a polished surface of a polished member polished by the polishing method of the present embodiment to a body to be connected, and may be a step of connecting a connection surface of a polished member polished by the polishing method of the present embodiment to a connection surface of a body to be connected. The connection surface of the polished member may be a polished surface polished by the polishing method of the present embodiment. A connection body having the polished member and the body to be connected can be obtained by the connecting step. In the connecting step, in a case where the connection surface of the polished member has a metal portion, the body to be connected may be connected to the metal portion. In the connecting step, in a case where the connection surface of the polished member has a metal portion and the connection surface of the body to be connected has a metal portion, the metal portions may be connected to each other. The metal portion may contain copper.

A device of the present embodiment (for example, an electronic device such as a semiconductor device) has at least one selected from the group consisting of the polished member polished by the polishing method of the present embodiment and the component of the present embodiment.

### EXAMPLES

Hereinafter, the present disclosure will be specifically described on the basis of Examples; however, the present disclosure is not limited to these Examples.

### <Preparation of Ceria Powder>

40 kg of cerium carbonate hydrate was divided into ten, placed in ten of alumina containers, respectively, and fired at 830° C. for 2 hours in air to obtain 20 kg of yellowish-white powder in total. The phase identification of this powder was performed by an X-ray diffraction method, and it was confirmed that this powder contained polycrystalline ceria. The particle diameter of the powder obtained by firing was observed with a SEM and was found to be in a range of 20 to 100 μm. Next, 20 kg of the ceria powder was subjected to dry pulverization using a jet mill to obtain a ceria powder. The specific surface area of the ceria powder after pulverization was 9.4 m²/g. The measurement of the specific surface area was performed by the BET method.

### <Preparation of Slurry>

15.0 kg of the aforementioned ceria powder and 84.5 kg of deionized water were placed in a container and mixed. Next, 0.5 kg of 1 M (mol/L, about 6% by mass) of acetic acid was added, and then stirring was performed for 10 minutes to obtain a ceria mixed liquid. This ceria mixed liquid was conveyed into another container over 30 minutes. During that time, the ceria mixed liquid was subjected to ultrasonic irradiation at an ultrasonic wave frequency of 400 kHz in the tube for conveying it.

A 800 g±8 g portion of the ceria mixed liquid conveyed through the ultrasonic irradiation was divided into four 1000 mL polyethylene containers. The ceria mixed liquid in each container was subjected to centrifugal separation for 20 minutes under conditions with an outer peripheral centrifugal force of 500 G. After the centrifugal separation, the supernatant fraction in the container was collected to obtain a slurry. The slurry contained about 10.0% by mass of ceria particles (abrasive grains) on the basis of the total mass of the slurry.

### <Preparation of Polishing Liquid>

A polishing liquid was prepared by mixing components shown in Table 1 according to the following procedure. First, components except for water (ultrapure water) were placed in a container. Next, water (ultrapure water) was poured into this container, and each component was dissolved by stirring. Subsequently, the slurry of the aforementioned abrasive grains (ceria particles) was mixed into this container, and then stirring was performed to obtain a polishing liquid. The content (the content of solids) of each component based on the total mass of the polishing liquid and the content of the halide ion based on the total amount of the polishing liquid are shown in Table 1. The remainder of the polishing liquid after removing the components of Table 1 is water.

As the components shown in Table 1, the following components were used.
Aromatic carboxylic acid A: Benzoic acid
Aromatic carboxylic acid B: Mandelic acid
Iodide salt A: Potassium iodide
Iodide salt B: Ammonium iodide
Iodide salt C: Tetrabutylammonium iodide
Bromide salt: Ammonium bromide
Chloride salt: Ammonium chloride
Fluoride salt: Ammonium fluoride
Nitrate: Ammonium nitrate
Polyglycerol: Trade name “PGL #750” manufactured by Sakamoto Yakuhin Kogyo Co., Ltd., weight average molecular weight: 750
Cationic polymer: Dimethylamine/ammonia/epichlorohydrin polycondensate, trade name “UNISENCE KHE105L” manufactured by SENKA corporation

### <Measurement of Average Particle Diameter>

The average particle diameter of the abrasive grains in the polishing liquid was measured using a laser diffraction/scattering particle size distribution measuring device (manufactured by MicrotracBEL Corp., trade name: Microtrac MT3300EXII), and as a result, the average particle diameter in each polishing liquid was 280 nm.

### <Measurement of Zeta Potential>

The zeta potential of the abrasive grains in the polishing liquid of Examples was measured using a zeta potential measuring apparatus (trade name: DELSANANO C manufactured by Beckman Coulter, Inc.). A sample was obtained by diluting the polishing liquid with water so that the scattering intensity of a measurement sample became 1.0×10⁴ to 5.0×10⁴ cps in the zeta potential measuring apparatus. After that, the sample was placed in a cell for measuring the zeta potential, and the zeta potential was measured. The results are shown in Table 1.

<Measurement of pH>

The pH of the polishing liquid was measured under the following conditions. The results are shown in Table 1.
Measurement temperature: 25±5° C.
Measuring apparatus: HORIBA, Ltd., trade name: Model (D-71)
Measurement method: the pH meter was calibrated by three points using a pH standard solution (pH 4.01) of a phthalate, a pH standard solution (pH 6.86) of a neutral phosphate, and a pH standard solution (pH 9.18) of a borate as pH standard solutions, an electrode of the pH meter was then put into the polishing liquid, and the stable value was measured at the time after 2 min or longer elapsed.

### <Polishing Evaluation>

As a base substrate (member to be polished) for polishing evaluation, the following pattern wafer (PTW) and blanket wafer (BKW) were prepared.

A 2 cm square pattern wafer (PTW), which had a silicon oxide film having 21 linear convex portions arranged parallel to each other with a spacing of 570 μm and having a length of 12 mm, a width of 30 μm, and a height of 4.5 to 6.0 μm in a center portion of a surface thereof, was prepared.

A laminate having a 2 μm-thick silicon oxide film formed on a silicon substrate by a CVD method was cut into 2 cm square to prepare a blanket wafer (BKW) having no patterns.

The aforementioned base substrate was fixed to a holder, to which an adsorption pad for mounting a base substrate was attached, of a polishing apparatus (manufactured by NANO FACTOR, trade name: FACT-200). The holder was placed on a platen attached with a polishing cloth of foamed polyurethane with the silicon oxide film of the base substrate faced down, and then a weight was placed with a processing load of 500 g/cm². The rotation speed of the platen was set to 120 min⁻¹, and the base substrate was polished while the aforementioned polishing liquid was added dropwise onto the platen at 5 mL/min. The polishing time for the pattern wafer was 60 seconds, and the polishing time for the blanket wafer was 180 seconds. In Comparative Examples, the blanket wafer was not polished, but the pattern wafer was polished. The polishing rate was calculated on the basis of a film thickness difference obtained by measuring the film thicknesses of the silicon oxide film before and after polishing using a light interference type film thickness measuring apparatus (manufactured by Toho Technology Corporation, trade name: TohoSpec3100). The results are shown in Table 1.

TABLE 1

| | Example | | | | | | | Comparative Example | | | |
|---|---|---|---|---|---|---|---|---|---|---|---|
| | 1 | 2 | 3 | 4 | 5 | 6 | 7 | 1 | 2 | 3 | 4 |
| Abrasive grains | 1.00 | 1.00 | 1.00 | 1.00 | 1.00 | 1.00 | 1.00 | 1.00 | 1.00 | 1.00 | 1.00 |
| Aromatic | 0.16 | 0.16 | 0.16 | 0.16 | 0.16 | 0.16 | 0.16 | 0.16 | 0.16 | | |
| carboxylic acid | | | | | | | | | | | |
| A | | | | | | | | | | | |
| Aromatic | 0.06 | 0.06 | 0.06 | 0.06 | 0.06 | 0.06 | 0.06 | 0.06 | 0.06 | | |
| carboxylic acid | | | | | | | | | | | |
| B | | | | | | | | | | | |
| Iodide salt A | 0.01 | | | | | | | | | 0.01 | |
| Iodide salt B | | 0.01 | 0.01 | | | | | | | | |
| Iodide salt C | | | | 0.0255 | | | | | | | |
| Bromide salt | | | | | 0.00676 | | | | | | |
| Chloride salt | | | | | | 0.00369 | | | | | |
| Fluoride salt | | | | | | | 0.00256 | | | | |
| Nitrate | | | | | | | | 0.00552 | | | |
| Polyglycerol | 0.20 | 0.20 | 0.20 | 0.20 | 0.20 | 0.20 | 0.20 | 0.20 | 0.20 | 0.20 | 0.20 |
| Cationic | 0.0016 | 0.0016 | | | | | | | 0.0016 | | |
| polymer | | | | | | | | | | | |
| Content of | 0.60 | 0.69 | 0.69 | 0.69 | 0.69 | 0.69 | 0.69 | — | — | 0.60 | — |
| halide ion | | | | | | | | | | | |
| [mM] | | | | | | | | | | | |
| Zeta potential | 20.0-25.0 | 22.7 | 20.0 | 20.2 | 24.3 | 25.6 | 24.5 | — | — | — | — |
| [mV] | | | | | | | | | | | |
| pH | 2.99 | 3.04 | 3.05 | 3.03 | 3.01 | 3.01 | 3.16 | 3.01 | 2.97 | 4.73 | 4.51 |
| PTW polishing | 3494 | 4202 | 5276 | 5174 | 4083 | 4420 | 4774 | 2230 | 2184 | 559 | 129 |
| rate [nm/min] | | | | | | | | | | | |
| BKW polishing | 52 | 50 | 792 | 656 | 875 | 938 | 2807 | — | — | — | — |
| rate [Å/min] | | | | | | | | | | | |

1. A polishing liquid comprising:
abrasive grains containing cerium oxide;
at least one aromatic carboxylic acid compound selected from the group consisting of an aromatic carboxylic acid and a salt thereof; and
a halide ion.

2. The polishing liquid according to claim 1, wherein the halide ion includes at least one selected from the group consisting of fluoride ion, chloride ion, bromide ion, and iodide ion.

3. The polishing liquid according to claim 1, wherein the halide ion includes iodide ion.

4. The polishing liquid according to claim 1, wherein a content of the halide ion is 0.01 to 5.0 mM.

5. The polishing liquid according to claim 1, wherein the aromatic carboxylic acid compound includes at least one selected from the group consisting of benzoic acid and a salt thereof.

6. The polishing liquid according to claim 1, wherein the aromatic carboxylic acid compound includes at least one selected from the group consisting of mandelic acid and a salt thereof.

7. The polishing liquid according to claim 1, wherein a content of the aromatic carboxylic acid compound is 0.01 to 1% by mass.

8. The polishing liquid according to claim 1, further comprising an alkali metal ion.

9. The polishing liquid according to claim 1, further comprising a nitrogen-containing cation.

10. The polishing liquid according to claim 9, wherein the nitrogen-containing cation includes at least one selected from the group consisting of an ammonium ion and a quaternary ammonium cation.

11. The polishing liquid according to claim 1, wherein a content of the abrasive grains is 0.1 to 5% by mass.

12. The polishing liquid according to claim 1, wherein a zeta potential of the abrasive grains is positive.

13. The polishing liquid according to claim 1, further comprising a cationic polymer.

14. The polishing liquid according to claim 13, wherein the cationic polymer includes a reaction product of a raw material containing at least dimethylamine and epichlorohydrin.

15. The polishing liquid according to claim 1, wherein a pH is 2.00 to 5.00.

16. A polishing method comprising: polishing a member to be polished by using the polishing liquid according to claim 1.

17. The polishing method according to claim 16, wherein the member to be polished contains silicon oxide.

18. A method for manufacturing a component, comprising: obtaining a component by using a polished member polished by the polishing method according to claim 16.

19. A method for manufacturing a semiconductor component, comprising: obtaining a semiconductor component by using a polished member polished by the polishing method according to claim 16.
